(19) United States
(12) Patent Application Publication
(10) Pub. No.: US 2022/0377904 A1
(43) Pub. Date: Nov. 24, 2022

(54) HIGH TEMPERATURE PRINTED CIRCUIT BOARD SUBSTRATE

(71) Applicant: 3D Glass Solutions, Inc., Albuquerque, NM (US)

(72) Inventor: Jeb H. Flemming, Albuquerque, NM (US)

(21) Appl. No.: 17/765,950

(22) PCT Filed: Oct. 6, 2020
(86) PCT No.: PCT/US2020/054394

§ 371 Date: Apr. 1, 2022

Related U.S. Application Data
(60) Provisional application No. 62/914,668, filed on Oct. 14, 2019.

(51) Int. Cl. H05K 3/00; H01L 23/15; H05K 1/03; H05K 3/12

(52) U.S. Cl. CPC H05K 3/0023; H01L 23/15; H05K 1/0306; H05K 3/1258; H05K 2201/068

(57) ABSTRACT

The present invention includes a method of creating high temperature mechanically and thermally stabilized PCB fabrication on a photo-definable glass substrate or photosensitive glass substrate.

### CROSS-REFERENCE TO RELATED APPLICATIONS

None.

### STATEMENT OF FEDERALLY FUNDED RESEARCH

None.

### TECHNICAL FIELD OF THE INVENTION

The present invention relates to creating a high temperature substrate for printed circuit board (PCB) applications.

### BACKGROUND OF THE INVENTION

Without limiting the scope of the invention, its background is described in connection with high temperature substrate for printed circuit board (PCB) applications. A number of applications such as automotive engine and gas turbine power production require high temperature semiconductor devices and PCB to be able to do active control to improve efficiency. Traditional printed circuit boards use polymers that have thermal properties that prevent normal operations above 80° C. A high temperature circuit board is typically defined as one with the Tg (glass transition temperature) greater than 170° C.

Designers and systems are continuously squeezing better performance out of printed circuit boards technology. With ever increasing power densities combined with high temperatures wreak havoc on conductors, dielectrics, active components and substrates. At elevated temperatures there are increased I²R losses. Environmental factors affect thermal and electrical impedances causing erratic system performance if not outright failure. Differences in thermal expansion rates exacerbated for substrates that are required to operate over large temperature ranges. The large temperature swings effect conductors and dielectrics and generate mechanical stresses that cause cracking and connection failures, especially if the boards are subject to cyclic heating and cooling. High temperature can even cause the dielectric (capacitive material) to lose its structural integrity altogether, eventually causing a system level cascade failure. Heat generation from either or both power-density circuits or high temperature environmental conditions have always been a factor in PCB performance, but frequently overwhelm traditional PCB thermal management or cooling system.

High temperature PCBs should follow a simple rule of thumb for continuous thermal load with an operating temperature ˜25° C. below the Tg.

### SUMMARY OF THE INVENTION

In one embodiment, the present invention includes a method of making a mechanically and thermally stabilized high temperature printed circuit board (PCB) comprising: masking a design layout comprising one or more structures that form one or more structures on a photosensitive glass substrate; exposing at least one portion of the photosensitive glass substrate to an activating energy source; heating the photosensitive glass substrate for at least ten minutes above its glass transition temperature; cooling the photosensitive glass substrate to transform at least part of the exposed glass into a glass-crystalline substrate; etching the glass-crystalline substrate with an etchant solution to form one or more trenches and a mechanical support under the design layout and one or more transmission line structures with electrical conduction elements; flood exposing all of the photosensitive glass substrate to an activating energy source; heating the photosensitive glass substrate for at least ten minutes above its glass transition temperature to form a ceramic substrate; printing or depositing one or more metals or metallic media that form the one or more electrical conduction elements, one or more filled vias, a ground plane, and one or more input and output channels; and placing a combination of active and passive elements on the one or more electrical conductive elements, filled via, or ground plane, wherein the metal is connected to a circuitry, and at least one of the electrical conductive elements. In one aspect, the mechanical support under the design layout and the one or more electrical conductive elements is a low loss tangent mechanical and thermal stabilization structure. In another aspect, the ceramic substrate is defined further as a fully ceramitized substrate. In another aspect, a thermal expansion coefficient of the ceramic substrate is greater than 7.2, or is 7.4, 7.5, 8.0, 8.5, 9.0, 9.5, 10, 10.4, or less than 10.5, or between 7.5 and 10. In another aspect, the one or more electrical conduction elements connect passive or active devices to form an electrical circuit. In another aspect, the step of etching forms one or more features that when filled with metals or oxides conductors form one or more electrically conductive lines or channels, wherein the structure is connected to one or more DC, RF, millimeter wave (mm wave) and terahertz frequencies electrical devices. In another aspect, the step of heating the substrate above its glass transition temperature (Tg) is applied for one or more process cycles to increase the Tg of the substrate where each processing cycle increases the Tg by a minimum of 50° C. to a maximum of 650° C. In another aspect, the metal is connected to the circuitry through a surface, a buried contact, a blind via, a glass via, a straight-line contact, a rectangular contact, a polygonal contact, or a circular contact. In another aspect, the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃, with the combination of B₂O₃; and Al₂O₃ not exceeding 13 weight %; 8-15 weight % Li₂O; and 0.001-0.1 weight % CeO₂. In another aspect, the photosensitive glass substrate is a glass substrate comprising a composition of: 35-76 weight % silica, 3-16 weight % K₂O, 0.003-1 weight % Ag₂O, 8-15 weight % Li₂O, and 0.001-0.1 weight % CeO₂. In another aspect, the photosensitive glass substrate is at least one of: a photo-definable glass substrate that comprises at least 0.1 weight % Sb2O3 or As2O3; a photo-definable glass substrate that comprises 0.003-1 weight % Au2O; a photo-definable glass substrate that comprises 1-18 weight % of an oxide selected from the group consisting of CaO, ZnO, PbO, MgO, SrO and BaO; and optionally has an anisotropic-etch ratio of exposed portion to unexposed portion that is at least one of 10-20:1; 21-29:1; 30-45:1; 20-40:1; 41-45:1; and 30-50:1. In another aspect, the photosensitive glass substrate is a photosensitive glass ceramic composite substrate comprising at least one of silica, lithium oxide, aluminum oxide, or cerium oxide. In another aspect, the RF transmission line device has a loss of less than 0.7 dB/cm at 30 Ghz. In another aspect, the method further comprises forming one or more RF mechanically and thermally stabilized PCB. The ceramic moves Tg up 200° C. to 650° C.

In another embodiment, the present invention includes a method of making a mechanically and thermally stabilized high temperature printed circuit board (PCB) comprising: exposing at least one portion of the photosensitive glass substrate previously masked with a design layout to an activating energy source; heating the photosensitive glass substrate for at least ten minutes above its glass transition temperature; cooling the photosensitive glass substrate to transform at least part of the exposed glass into a glass-crystalline substrate; etching the glass-crystalline substrate with an etchant to form one or more trenches and a mechanical support under the design layout and one or more electrical conduction elements; exposing the entire photosensitive glass substrate to an activating energy source; heating the photosensitive glass substrate for at least ten minutes above its glass transition temperature to form a ceramic substrate; printing or depositing one or more metals or metallic media that form the one or more electrical conduction elements, one or more filled vias, a ground plane, and one or more input and output channels; and placing a combination of active and passive elements on the one or more electrical conductive elements, filled via, or ground plane, wherein the metal is connected to a circuitry, and at least one of the electrical conductive elements. In another aspect, the step of heating the substrate above its glass transition temperature (Tg) is applied for one or more process cycles to increase the Tg of the substrate where each processing cycle increases the Tg by a minimum of 50° C. to a maximum of 650° C. In one aspect, the mechanical support under the design layout and the one or more electrical conductive elements is a low loss tangent mechanical and thermal stabilization structure. In another aspect, the ceramic substrate is defined further as a fully ceramitized substrate. In another aspect, a thermal expansion coefficient of the ceramic substrate is greater than 7.2, or is 7.4, 7.5, 8.0, 8.5, 9.0, 9.5, 10, 10.4, or less than 10.5, or between 7.5 and 10. In another aspect, the one or more electrical conduction elements connect passive or active devices to form an electrical circuit. In another aspect, the step of etching forms one or more features that when filled with metals or oxides conductors form one or more electrically conductive lines or channels, wherein the structure is connected to one or more DC, RF, millimeter wave (mm wave) and terahertz frequencies electrical devices. In another aspect, the metal is connected to the circuitry through a surface, a buried contact, a blind via, a glass via, a straight-line contact, a rectangular contact, a polygonal contact, or a circular contact. In another aspect, the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the photosensitive glass substrate is a glass substrate comprising a composition of: 35-76 weight % silica, 3-16 weight % K₂O, 0.003-1 weight % Ag₂O, 8-15 weight % Li₂O, and 0.001-0.1 weight % CeO₂. In another aspect, the photosensitive glass substrate is at least one of: a photo-definable glass substrate that comprises at least 0.1 weight % Sb2O3 or As2O3; a photo-definable glass substrate that comprises 0.003-1 weight % Au2O; a photo-definable glass substrate that comprises 1-18 weight % of an oxide selected from the group consisting of CaO, ZnO, PbO, MgO, SrO and BaO; and optionally has an anisotropic-etch ratio of exposed portion to unexposed portion that is at least one of 10-20:1; 21-29:1; 30-45:1; 20-40:1; 41-45:1; and 30-50:1. In another aspect, the photosensitive glass substrate is a photosensitive glass ceramic composite substrate comprising at least one of silica, lithium oxide, aluminum oxide, or cerium oxide. In another aspect, the RF transmission line device has a loss of less than 0.7 dB/cm at 30 Ghz. In another aspect, the method further comprises forming one or more RF mechanically and thermally stabilized PCB.

### BRIEF DESCRIPTION OF THE DRAWINGS

For a more complete understanding of the features and advantages of the present invention, reference is now made to the detailed description of the invention along with the accompanying FIGURES and in which:

FIG. 1 is a flowchart of one method of the present invention.

### DETAILED DESCRIPTION OF THE INVENTION

While the making and using of various embodiments of the present invention are discussed in below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims. The ceramic moves Tg up 200° C. to 650° C.

In one embodiment, the present invention includes a method of making a mechanically and thermally stabilized PCB substrate. The printed circuit board (PCB) device will be mechanically and thermally stabilized. Where the PCB substrate is made on a photosensitive glass substrate, as described herein, it is generally formed by; exposing at least one portion of the photosensitive glass substrate to an activating energy source; heating the photosensitive glass substrate for at least ten minutes above its glass transition temperature; cooling the photosensitive glass substrate to transform at least part of the exposed glass to a crystalline material to form a glass-crystalline substrate; etching the glass-crystalline substrate with an etchant; flood exposing all of remaining photosensitive glass substrate to an activating energy source; heating the photosensitive glass substrate for at least ten minutes above its glass transition temperature to form a ceramic substrate; cooling the photosensitive glass/ceramic substrate to transform the exposed glass to a crystalline material to form a glass-crystalline substrate; coating the one or more electrical conductive elements, ground plane and input and output channels with one or more metals, wherein the metal is connected to a circuitry. The mechanically and thermally stabilized PCB can be used for circuitry including DC, RF, millimeter wave (mm wave), and terahertz frequencies. The thermal expansion coefficient of the ceramic substrate, as measured linearly, is between 7.5 and 10 a, and in some cases is greater than 7.2, or is 7.4, 7.5, 8.0, 8.5, 9.0, 9.5, 10, 10.4, or less than 10.5. In one particular example, the step of heating the substrate above its glass transition temperature (Tg) is applied for one or more process cycles to increase the Tg of the substrate where each processing cycle increases the Tg by a minimum of 50° C. to a maximum of 650° C.

In one embodiment, the one or more metals are selected from Fe, Cu, Au, Ni, In, Ag, Pt, or Pd for the metallization. For higher temperature applications Pt and/or Pd can be used as the metallization. In another aspect, the metallization connects to the circuitry through a surface a buried contact, a blind via, a glass via, a straight-line contact, rectangular contact, a polygonal contact, or a circular contact.

In another aspect, the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; and the combination of B₂O₃; and Al₂O₃ not exceeding 13 weight %; 8-15 weight % Li₂O; and 0.001-0.1 weight % CeO₂. In another aspect, the photosensitive glass substrate is a glass substrate comprising a composition of: 35-76 weight % silica, 3-16 weight % K₂O, 0.003-1 weight % Ag₂O, 8-15 weight % Li₂O, and 0.001-0.1 weight % CeO₂. In another aspect, the photosensitive glass substrate is at least one of: a photo-definable glass substrate comprises at least 0.1 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO, SrO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the photosensitive glass substrate is a photosensitive glass ceramic composite substrate comprising at least one of silica, lithium oxide, aluminum oxide, or cerium oxide. In another aspect, the electronic circuit. In another aspect, the method further comprises forming the mechanically and thermally stabilized transmission line structure into a feature of at least one or more passive and active components to form bandpass, low pass, high pass, shunt or notch filter and other circuits.

The present invention relates to creating a high temperature replacement printed circuit board (PCB) substrate using a sapphire substrates using thin film additive processes on semiconductor, insulating or conductive substrates is expensive with low yield and a high variability in performance. An example of additive micro-transmission can be seen in articles Semiconductor Microfabrication Processes by Tian et al. rely on expensive capital equipment; photolithography and reactive ion etching or ion beam milling tools that generally cost in excess of one million dollars each and require an ultra-clean, high-production silicon fabrication facility costing millions to billions more. This invention provides a cost effective ceramic electronic individual device, or as an array of passive devices, for a uniform response for DC, RF, millimeter wave (mm wave) and terahertz frequencies.

Microstructures have been produced relatively inexpensively with these glasses using conventional semiconductor processing equipment. In general, glasses have high temperature stability, good mechanical and electrical properties, and have better chemical resistance than plastics and many metals. Photoetchable glass is comprised of lithium-aluminum-silicate glass containing traces of silver ions. When exposed to UV-light within the absorption band of cerium oxide, the cerium oxide acts as sensitizers, absorbing a photon and losing an electron that reduces neighboring silver oxide to form silver atoms, e.g.,

Ce³⁺+Ag⁺=Ce⁴⁺+Ag⁰

The silver atoms coalesce into silver nanoclusters during the baking process and induce nucleation sites for crystallization of the surrounding glass. If exposed to UV light through a mask, only the exposed regions of the glass will crystallize during subsequent heat treatment.

This heat treatment must be performed at a temperature near the glass transformation temperature (e.g., greater than 465° C. in air). The crystalline phase is more soluble in etchants, such as hydrofluoric acid (HF) than the unexposed vitreous, amorphous regions. The crystalline regions etched greater than 20 times faster than the amorphous regions in 10% HF, enabling microstructures with wall slopes ratios of about 20:1 when the exposed regions are removed. See T. R. Dietrich, et al., “Fabrication Technologies for Microsystems utilizing Photoetchable Glass”, Microelectronic Engineering 30,497 (1996), relevant portions of which are incorporated herein by reference.

The exposed portion may be transformed into a crystalline material by heating the glass substrate to a temperature near the glass transformation temperature. When etching the glass substrate in an etchant such as hydrofluoric (HF) acid, the anisotropic-etch ratio of the exposed portion to the unexposed portion is at least 30:1, when the glass is exposed to a broad spectrum mid-ultraviolet (about 308-312 nm) flood lamp to provide a shaped glass structure that has an aspect ratio of at least 30:1, and to provide a lens shaped glass structure. The exposed glass is then baked typically in a two-step process. Temperature range heated between of 420° C.-520° C. for between 10 minutes to 2 hours. For the coalescing of silver ions into silver nanoparticles the temperature range for heating is between 520° C.-620° C. for between 10 minutes and 2 hours allowing the lithium oxide to form around the silver nanoparticles. The glass plate is then etched. The glass substrate is etched in an etchant of HF solution, typically 5% to 10% by volume, where in the etch ratio of exposed portion to that of the unexposed portion is at least 30:1. The etched features created can be filled with metals, dielectrics, and/or resistive elements and combined with, or connected to, active devices to form circuits. The final processing steps prior to the creation of the electric circuits and structures in photoetchable glass structure is to fully convert the remaining glass substrate to a ceramic phase. The ceramicization of the glass is accomplished by exposing all of the remaining photodefinable glass substrate to approximately 20 J/cm² of 310 nm light. Then the substrate is heated to a temperature to between 420° C.-520° C. for up to 2 hours. In one particular example, the step of heating the substrate above its glass transition temperature (Tg) is applied for one or more process cycles to increase the Tg of the substrate where each processing cycle increases the Tg by a minimum of 50° C. to a maximum of 650° C. For the coalescing of silver ions into silver nanoparticles the temperature range for heating is between 520° C.-620° C. for between 10 minutes and 2 hours, which allows lithium oxide to form around the silver nanoparticles. The substrate is then cooled and then processed to add metalized structures (interconnects, via and others). Finally the active and passive devices are placed on to the ceramitized substrate. The Tg of the photodefinable glass can be increased through the exposure and thermal cycling from 200° C. to 650° C. 200° C. is the Tg for the un-exposed nanocrystalline photodefinable glass ceramic material. On full cycle increases the Tg to 600° C. Subsequent thermal and photo exposures can increase the Tg to 650° C. This increase requires a minimum of two exposures,

The present invention includes a method of making a mechanically and thermally stabilized high temperature printed circuit board (PCB) comprising, consisting essentially of, or consisting of: masking a design layout comprising one or more structures that form one or more structures on a photosensitive glass substrate; exposing at least one portion of the photosensitive glass substrate to an activating energy source; heating the photosensitive glass substrate for at least ten minutes above its glass transition temperature; cooling the photosensitive glass substrate to transform at least part of the exposed glass into a glass-crystalline substrate; etching the glass-crystalline substrate with an etchant solution to form one or more trenches and a mechanical support under the design layout and one or more transmission line structures with electrical conduction elements; flood exposing all of the photosensitive glass substrate to an activating energy source; heating the photosensitive glass substrate for at least ten minutes above its glass transition temperature to form a ceramic substrate; printing or depositing one or more metals or metallic media that form the one or more electrical conduction elements, one or more filled vias, a ground plane, and one or more input and output channels; and placing a combination of active and passive elements on the one or more electrical conductive elements, filled via, or ground plane, wherein the metal is connected to a circuitry, and at least one of the electrical conductive elements.

The present invention also includes a method of making a mechanically and thermally stabilized high temperature printed circuit board (PCB) comprising, consisting essentially of, or consisting of: exposing at least one portion of the photosensitive glass substrate previously masked with a design layout to an activating energy source; heating the photosensitive glass substrate for at least ten minutes above its glass transition temperature; cooling the photosensitive glass substrate to transform at least part of the exposed glass into a glass-crystalline substrate; etching the glass-crystalline substrate with an etchant to form one or more trenches and a mechanical support under the design layout and one or more electrical conduction elements; exposing the entire photosensitive glass substrate to an activating energy source; heating the photosensitive glass substrate for at least ten minutes above its glass transition temperature to form a ceramic substrate; printing or depositing one or more metals or metallic media that form the one or more electrical conduction elements, one or more filled vias, a ground plane, and one or more input and output channels; and placing a combination of active and passive elements on the one or more electrical conductive elements, filled via, or ground plane, wherein the metal is connected to a circuitry, and at least one of the electrical conductive elements.

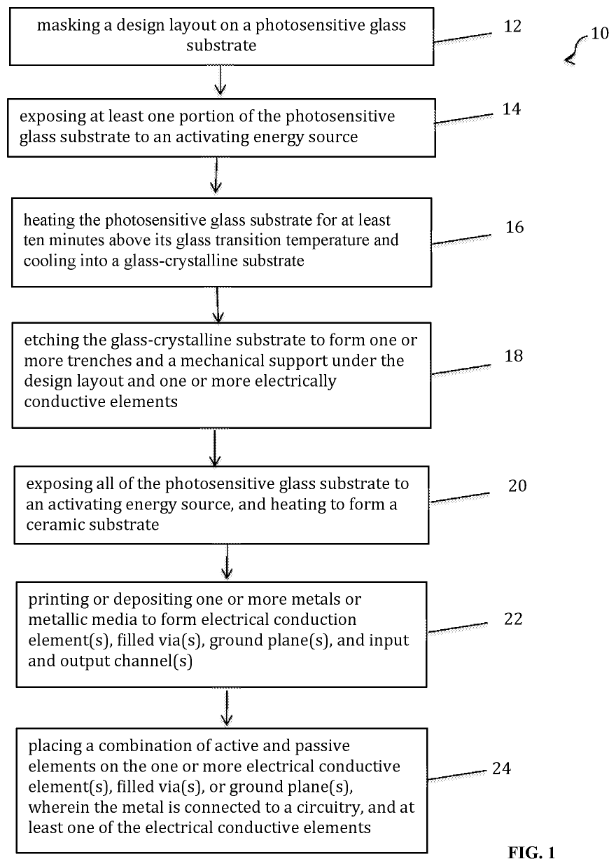

FIG. 1 is a flowchart 10 that shows one method of making a mechanically and thermally stabilized high temperature printed circuit board (PCB). In step 12, the step is masking a design layout comprising one or more structures that form one or more structures on a photosensitive glass substrate. In step 14, the step is exposing at least one portion of the photosensitive glass substrate to an activating energy source. In step 16, the step is heating the photosensitive glass substrate for at least ten minutes above its glass transition temperature followed by cooling the photosensitive glass substrate to transform at least part of the exposed glass into a glass-crystalline substrate. In step 18, the step is etching the glass-crystalline substrate with an etchant solution to form one or more trenches and a mechanical support under the design layout and one or more transmission line structures with electrical conduction elements. In step 20, the step is exposing all of the photosensitive glass substrate to an activating energy source, e.g., by flood exposing the substrate and heating the photosensitive glass substrate for at least ten minutes above its glass transition temperature to form a ceramic substrate. In step 22, the step is printing or depositing one or more metals or metallic media that form the one or more electrical conduction elements, one or more filled vias, a ground plane, and one or more input and output channels. Finally, in step 24, the step is and placing a combination of active and passive elements on the one or more electrical conductive elements, filled via, or ground plane, wherein the metal is connected to a circuitry, and at least one of the electrical conductive elements.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. A method of making a mechanically and thermally stabilized high temperature printed circuit board (PCB) comprising:
masking a design layout comprising one or more structures that form one or more structures on a photosensitive glass substrate;
exposing at least one portion of the photosensitive glass substrate to an activating energy source;
heating the photosensitive glass substrate for at least ten minutes above its glass transition temperature;
cooling the photosensitive glass substrate to transform at least part of the exposed glass into a glass-crystalline substrate;
etching the glass-crystalline substrate with an etchant solution to form one or more trenches and a mechanical support under the design layout and one or more transmission line structures with electrical conduction elements;
flood exposing all of the photosensitive glass substrate to an activating energy source;
heating the photosensitive glass substrate for at least ten minutes above its glass transition temperature to form a ceramic substrate;
printing or depositing one or more metals or metallic media that form the one or more electrical conduction elements, one or more filled vias, a ground plane, and one or more input and output channels; and
placing a combination of active and passive elements on the one or more electrical conductive elements, filled via, or ground plane, wherein the metal is connected to a circuitry, and at least one of the electrical conductive elements.

2. The method of claim 1, wherein the mechanical support under the design layout and the one or more electrical conductive elements is a low loss tangent mechanical and thermal stabilization structure.

3. The method of claim 1, wherein the ceramic substrate is defined further as a ceramitized substrate.

4. The method of claim 1, wherein a thermal expansion coefficient of the ceramic substrate is greater than 7.2, or is 7.4, 7.5, 8.0, 8.5, 9.0, 9.5, 10, 10.4, or less than 10.5, or between 7.5 and 10.

5. The method of claim 1, wherein the one or more electrical conduction elements connect passive or active devices to form an electrical circuit.

6. The method of claim 1, wherein the step of heating the substrate above its glass transition temperature (Tg) is applied for one or more process cycles to increase the Tg of the substrate where each processing cycle increases the Tg by a minimum of 50° C. to a maximum of 650° C.

7. The method of claim 1, wherein the step of etching forms one or more features that when filled with metals or oxides conductors form one or more electrically conductive lines or channels, wherein the structure is connected to one or more DC, RF, millimeter wave (mm wave) and terahertz frequencies electrical devices.

8. The method of claim 1, wherein the metal is connected to the circuitry through a surface, a buried contact, a blind via, a glass via, a straight-line contact, a rectangular contact, a polygonal contact, or a circular contact.

9. The method of claim 1, wherein the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂.

10. The method of claim 1, wherein the photosensitive glass substrate is a glass substrate comprising a composition of: 35-76 weight % silica, 3-16 weight % K₂O, 0.003-1 weight % Ag₂O, 8-15 weight % Li₂O, and 0.001-0.1 weight % CeO₂.

11. The method of claim 1, wherein the photosensitive glass substrate is at least one of: a photo-definable glass substrate that comprises at least 0.1 weight % Sb2O3 or As2O3; a photo-definable glass substrate that comprises 0.003-1 weight % Au2O; a photo-definable glass substrate that comprises 1-18 weight % of an oxide selected from the group consisting of CaO, ZnO, PbO, MgO, SrO and BaO; and optionally has an anisotropic-etch ratio of exposed portion to unexposed portion that is at least one of 10-20:1; 21-29:1; 30-45:1; 20-40:1; 41-45:1; and 30-50:1.

12. The method of claim 1, wherein the photosensitive glass substrate is a photosensitive glass ceramic composite substrate comprising at least one of silica, lithium oxide, aluminum oxide, or cerium oxide.

13. The method of claim 1, wherein the RF transmission line device has a loss of less than 0.7 dB/cm at 30 Ghz.

14. The method of claim 1, further comprising forming one or more RF mechanically and thermally stabilized PCB.

15. A method of making a mechanically and thermally stabilized high temperature printed circuit board (PCB) comprising:
exposing at least one portion of the photosensitive glass substrate previously masked with a design layout to an activating energy source;
heating the photosensitive glass substrate for at least ten minutes above its glass transition temperature;
cooling the photosensitive glass substrate to transform at least part of the exposed glass into a glass-crystalline substrate;
etching the glass-crystalline substrate with an etchant to form one or more trenches and a mechanical support under the design layout and one or more electrical conduction elements;
exposing the entire photosensitive glass substrate to an activating energy source;
heating the photosensitive glass substrate for at least ten minutes above its glass transition temperature to form a ceramic substrate;
printing or depositing one or more metals or metallic media that form the one or more electrical conduction elements, one or more filled vias, a ground plane, and one or more input and output channels; and
placing a combination of active and passive elements on the one or more electrical conductive elements, filled via, or ground plane, wherein the metal is connected to a circuitry, and at least one of the electrical conductive elements.

16. The method of claim 15, wherein the mechanical support under the design layout and the one or more electrical conductive elements is a low loss tangent mechanical and thermal stabilization structure.

17. The method of claim 15, wherein the ceramic substrate is defined further as a fully ceramitized substrate.

18. The method of claim 15, wherein the step of heating the substrate above its glass transition temperature (Tg) is applied for one or more process cycles to increase the Tg of the substrate where each processing cycle increases the Tg by a minimum of 50° C. to a maximum of 650° C.

19. The method of claim 15, wherein a thermal expansion coefficient of the ceramic substrate is greater than 7.2, or is 7.4, 7.5, 8.0, 8.5, 9.0, 9.5, 10, 10.4, or less than 10.5, or is between 7.5 to 10.

20. The method of claim 15, wherein the one or more electrical conductive elements connect passive or active devices to form an electrical circuit.

21. The method of claim 15, wherein the step of etching forms one or more features that when filled with metals or oxides conductors form one or more electrical conductive lines or channels, wherein the structure is connected to one or more DC, RF, millimeter wave (mm wave) and terahertz frequencies electrical devices.

22. The method of claim 15, wherein the metal is connected to the circuitry through a surface, a buried contact, a blind via, a glass via, a straight-line contact, a rectangular contact, a polygonal contact, or a circular contact.

23. The method of claim 15, wherein the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂.

24. The method of claim 15, wherein the photosensitive glass substrate is a glass substrate comprising a composition of: 35-76 weight % silica, 3-16 weight % K₂O, 0.003-1 weight % Ag₂O, 8-15 weight % Li₂O, and 0.001-0.1 weight % CeO₂.

25. The method of claim 15, wherein the photosensitive glass substrate is at least one of: a photo-definable glass substrate that comprises at least 0.1 weight % Sb₂O₃ or As₂O₃; a photo-definable glass substrate that comprises 0.003-1 weight % Au2O; a photo-definable glass substrate that comprises 1-18 weight % of an oxide selected from the group consisting of CaO, ZnO, PbO, MgO, SrO and BaO; and optionally has an anisotropic-etch ratio of exposed portion to unexposed portion that is at least one of 10-20:1; 21-29:1; 30-45:1; 20-40:1; 41-45:1; and 30-50:1.

26. The method of claim 15, wherein the photosensitive glass substrate is a photosensitive glass ceramic composite substrate comprising at least one of silica, lithium oxide, aluminum oxide, or cerium oxide.

27. The method of claim 15, wherein the RF transmission line device has a loss of less than 0.7 dB/cm at 30 Ghz.

28. The method of claim 15, further comprising forming one or more RF mechanically and thermally stabilized PCB.
